(19) United States
(12) Patent Application Publication
(10) Pub. No.: US 2011/0164391 A1
(43) Pub. Date: Jul. 7, 2011

(54) ELECTRONIC COMPONENT-EMBEDDED PRINTED CIRCUIT BOARD AND METHOD OF MANUFACTURING THE SAME

(76) Inventors: Yee Na SHIN, Seoul (KR); Tae Sung JEONG, Gyunggi-do (KR); Young Ki LEE, Gyunggi-do (KR); Seung Eun LEE, Gyunggi-do (KR)

(21) Appl. No.: 12/775,341

(22) Filed: May 6, 2010

(30) Foreign Application Priority Data
Jan. 6, 2010 (KR) 10-2010-0000910

(51) Int. Cl. H05K 1/18; H05K 3/00

(52) U.S. Cl. 361/761; 216/13; 427/97.1

(57) ABSTRACT

Disclosed herein is an electronic component-embedded printed circuit board, including: a metal substrate including an anodic oxide film formed over the entire surface thereof; two electronic components disposed in a cavity formed in the metal substrate in two stages; an insulation layer formed on both sides of the metal substrate to bury the electronic components disposed in the cavity; and circuit layers including vias connected with connecting terminals of the electronic components and formed on the exposed surfaces of the insulation layer. The electronic component-embedded printed circuit board is advantageous in that its radiation performance of radiating the heat generated from an electronic component can be improved, and its production cost can be reduced, because a metal substrate is used instead of a conventional insulating material.

### CROSS REFERENCE TO RELATED APPLICATION

This application claims the benefit of Korean Patent Application No. 10-2010-0000910, filed Jan. 6, 2010, entitled “A printed circuit board comprising embedded electronic component within and a method for manufacturing the same”, which is hereby incorporated by reference in its entirety into this application.

### BACKGROUND OF THE INVENTION

1. Technical Field

The present invention relates to an electronic component-embedded printed circuit board and a method of manufacturing the same.

2. Description of the Related Art

Various technologies are required to realize a printed circuit board in a market which requires semiconductor packages having decreased profiles and a variety of functions.

For example, in the manufacturing of a flip chip ball grid array (FCBGA) package, the electroconductive terminals or lands of ICs are directly soldered to the lands corresponding to the die bonding region on the surface of a substrate using reflowable solder bumps or balls. In this case, electronic components are functionally connected to other elements of an electronic system through electroconductive channels including substrate traces, and the substrate traces generally serve to transport signals transmitted between electronic components such as ICs and the like. In the case of FCBGA, ICs located at the upper end of a substrate and capacitors located at the lower end thereof are surface-mounted, respectively. In this case, the length of a circuit path for connecting the IC with the capacitor, that is, a connection circuit, is increased by the thickness of the substrate, so that impedance is increased, thereby deteriorating electrical performance. Further, since a part of the lower end of the substrate must be used to mount chips, design flexibility is limited, for example, users desiring to mount a ball array over the entire surface of the lower end thereof will be left unsatisfied.

In order to solve the above problems, electronic component packaging technologies for shortening the circuit path by embedding electronic components in a substrate are becoming popular. Since electronic component-embedded printed circuit boards (PCBs) are provided in the organic substrate thereof with active/passive electronic components mounted on a conventional substrate in the form of package, a kind of next-generation three dimensional packaging technology, which can satisfy the multi-functionality attributable to the insurance of a residual surface area, the low loss of high frequency/high efficiency attributable to the minimization of signal transfer lines, and the miniaturization of the printed circuit board, can be developed, and a novel highly-functional packaging trend can be induced.

FIGS. 1A to 1E are sectional views sequentially showing a conventional method of manufacturing an electronic component-embedded printed circuit board. Hereinafter, conventional problems will be described with reference to FIGS. 1A to 1E.

First, as shown in FIG. 1A, there is provided a substrate 10 including: an insulation layer 3 having a cavity 2 in which an electronic component 1 can be disposed and first circuit patterns 11 formed on both sides thereof; and a tape 4 adhered to one side of the insulation layer 3.

Subsequently, as shown in FIG. 1B, the electronic component 1 is disposed in the cavity 2 of the insulation layer 3. In this case, the electronic component 1 is installed in the cavity 2 in a face-up manner using a vacuum adsorption header (not shown), and is supported by the tape 4.

Subsequently, as shown in FIG. 1C, an insulating material layer 5 is formed on the substrate 10 including the cavity 2. The insulating material layer 5 is formed in the cavity 2 provided therein with the electronic component 1, and thus the electronic component 1 is buried in the insulating material layer 5.

Subsequently, as shown in FIG. 1D, the tape 4 is removed from the substrate 10. Since the tape 4 serves to support the electronic component 1 before the electronic component is fixed in the substrate 10 by the insulating material layer 5, it is removed after the insulating material layer 5 is formed.

Subsequently, as shown in FIG. 1E, an insulating material layer 5 is formed even on the one side of the insulation layer 3 from which the tape 4 was removed, so that the electronic component 1 can be embedded in the substrate 10, and then circuit layers 8 including vias 6 and second circuit patterns 7 are formed on both sides of the insulating material layer 5. In this case, the vias 6 are electrically connected with the connecting terminals 9 of the electronic component 1.

Here, the conventional electronic component-embedded printed circuit board is problematic in that its performance of radiating the heat generated from an electronic component is decreased because an insulating material is used, and in that its total production cost is increased because the insulating material constituting an insulation layer is expensive.

Further, the conventional electronic component-embedded printed circuit board is problematic in that it is difficult to ensure its structural stability because it is greatly warped due to the difference in thermal expansion coefficient between the insulating material and the electronic component.

### SUMMARY OF THE INVENTION

Accordingly, the present invention has been made to solve the above-mentioned problems, and the present invention provides an electronic component-embedded printed circuit board which can improve its performance of radiating the heat generated from an electronic component by employing a metal substrate coated with an anodic oxide film and which can ensure its overall structural stability by disposing two electronic components in two stages, and a method of manufacturing the same.

An aspect of the present invention provides an electronic component-embedded printed circuit board, including: a metal substrate including an anodic oxide film formed over the entire surface thereof; two electronic components disposed in a cavity formed in the metal substrate in two stages; an insulation layer formed on both sides of the metal substrate to bury the electronic components disposed in the cavity; and circuit layers including vias connected with connecting terminals of the electronic components and formed on the exposed surfaces of the insulation layer.

Here, the electronic component-embedded printed circuit board may further include a support plate which is formed in the cavity to divide the cavity into two parts in a thickness direction and which supports the two electronic components on both sides thereof.

Further, the electronic component-embedded printed circuit board may further include an adhesive layer applied onto both sides of the support plate to fix the two electronic components.

Further, the electronic component-embedded printed circuit board may further include one or more openings passing through the support plate.

Further, the support plate may be extended from the metal substrate and be integrated therewith.

Further, the electronic component-embedded printed circuit board may further include: two metal substrates disposed in two stages; and an adhesive layer attaching the two metal substrates to each other.

Further, the electronic component-embedded printed circuit board may further include through-holes which pass through the insulation layer and the metal substrate and which communicate with the circuit layers.

Further, the metal substrate may be made of aluminum (Al), and the anodic oxide film may be made of alumina (Al₂O₃).

Another aspect of the present invention provides a method of manufacturing an electronic component-embedded printed circuit board, including: forming a cavity in a metal substrate and then forming an anodic oxide film over the entire surface of the metal substrate; disposing two electronic components in the cavity in two stages; forming an insulation layer on both sides of the metal substrate to bury the electronic components disposed in the cavity; and forming circuit layers including vias connected with connecting terminals of the electronic components on the exposed surfaces of the insulation layer.

Here, in the forming of the cavity, a support plate for dividing the cavity into two parts in a thickness direction may be formed by leaving the central portion of the metal substrate to a predetermined thickness when the cavity is formed by removing the predetermined portion of the metal substrate through an etching process.

Further, in the disposing of two electronic components, an adhesive layer may be applied onto both sides of the support plate to fix the two electronic components.

Further, in the forming of the cavity, one or more openings passing through the support plate may be formed when the support plate is formed.

Further, the forming of the circuit layers may further include: forming through-holes which pass through the insulation layer and the metal substrate and which communicate with the circuit layers.

Further, in the forming of the cavity and the anodic oxide film, the metal substrate may be made of aluminum (Al), and the anodic oxide film may be made of alumina (Al₂O₃).

Still another aspect of the present invention provides a method of manufacturing an electronic component-embedded printed circuit board, including: forming cavities in two metal substrates and then forming anodic oxide films over the entire surfaces of the two metal substrates through an anodic oxidation process; disposing electronic components in the cavities; applying insulation layers onto the one sides of the respective two metal substrates to bury the electronic components disposed in the cavities; attaching the two metal substrates provided with the insulation layers to each other using an adhesive layer; and forming circuit layers including vias connected with connecting terminals of the electronic components on the exposed surfaces of the insulation layers.

Here, the forming of the circuit layers may further include: forming through-holes which pass through the insulation layers and the metal substrates and which communicate with the circuit layers.

Further, in the forming of the cavity and the anodic oxide film, each of the metal substrates may be made of aluminum (Al), and each of the anodic oxide films may be made of alumina (Al₂O₃).

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1E are sectional views sequentially showing a conventional method of manufacturing an electronic component-embedded printed circuit board;

FIG. 2 is a sectional view showing an electronic component-embedded printed circuit board according to a first embodiment of the present invention;

FIG. 3 is a sectional view showing an electronic component-embedded printed circuit board according to a second embodiment of the present invention;

FIGS. 4 to 9 are sectional views sequentially showing a method of manufacturing the electronic component-embedded printed circuit board according to the first embodiment of the present invention; and

FIGS. 10 to 15 are sectional views sequentially showing a method of manufacturing the electronic component-embedded printed circuit board according to the second embodiment of the present invention.

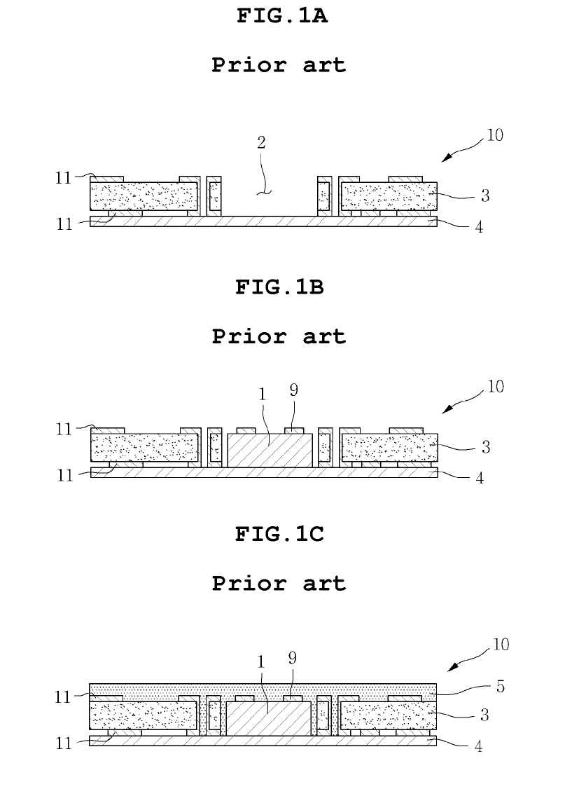

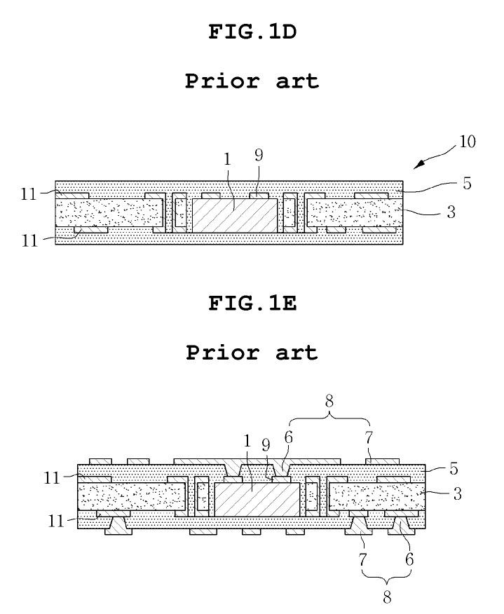

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

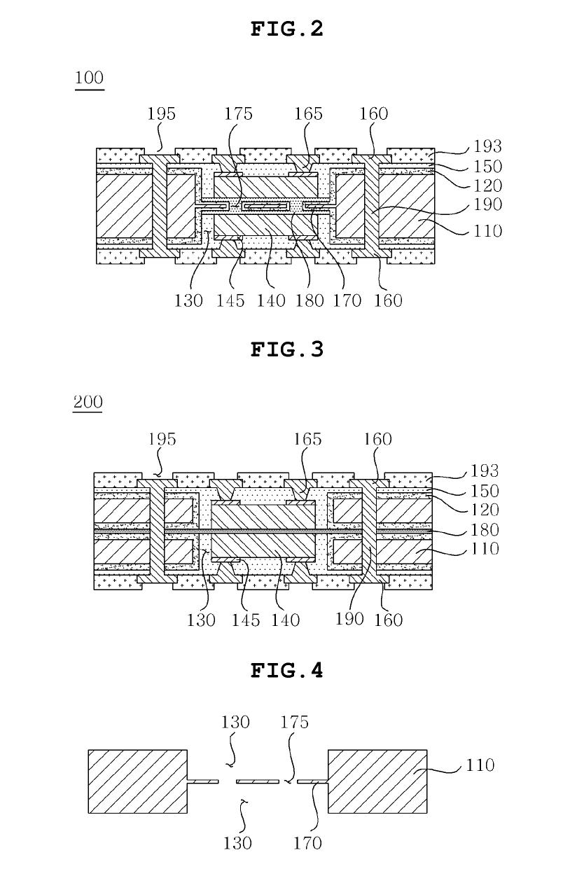

FIG. 2 is a sectional view showing an electronic component-embedded printed circuit board according to a first embodiment of the present invention.

As shown in FIG. 2, the electronic component-embedded printed circuit board 100 according to the first embodiment of the present invention includes: a metal substrate 110 including an anodic oxide film 120 formed over the entire surface thereof; two electronic components 140 disposed in a cavity 130 formed in the metal substrate 110 in two stages; an insulation layer 150 formed on both sides of the metal substrate 110 to bury the electronic components 140 disposed in the cavity 130; and circuit layers 160 including vias 165 connected with connecting terminals 145 of the electronic components 140 and formed on the exposed surfaces of the insulation layer 150.

The metal substrate 110 serves as the core of the electronic component-embedded printed circuit board and may be made of a metal having high rigidity and excellent thermal conductivity, such as aluminum (Al), magnesium (Mg), titanium (Ti) or the like. Further, an anodic oxide film 120 may be formed over the entire surface of the metal substrate 110 in order to prevent the short of the metal substrate 110, circuit patterns or the like. Here, the anodic oxide film 120 can be formed by a metal acting as an anode in a sulfuric acid solution to accelerate the oxidation of the surface of the metal. This process is referred to as an anodic oxidation process. For example, when the metal substrate 110 is made of aluminum (Al), an anodic oxide film made of alumina (Al₂O₃) can be formed over the entire surface of the metal substrate 110 through the anodic oxidation process. The metal substrate can improve the radiation performance of the printed circuit board because it has excellent thermal conductivity, and can reduce the warpage of the printed circuit board because it has relatively high rigidity.

Meanwhile, the metal substrate 110 must be provided therein with a cavity 130 for disposing the electronic components 140. Although methods of forming the cavity 130 are not particularly limited, the cavity 130 may be formed by removing the predetermined portion of the metal substrate 110 through a wet etching process or a dry etching process. Further, the metal substrate 110 may be provided therein with a support plate 170 for stably supporting the two electronic components. The support plate 170 is formed in the cavity 130 such that the cavity 130 is divided into two parts in a thickness direction, and the two electronic components are disposed on both sides of the support plate 170, respectively. Here, the support plate 170 can be formed by leaving a part of the metal substrate 110 at the time of forming the cavity 130 in the metal substrate 110 through an etching process, and, in this case, the support plate 170 is integrated with the metal substrate 110. When the support plate 170 and the metal substrate 110 are integrally formed, there is an advantage in that the heat generated from the electronic components 140 can be effectively radiated through the support plate 170.

Further, an adhesive layer 180 may be applied on both sides of the support plate 170 to fix the electronic components on the both sides thereof. In order to uniformly apply the adhesive layer 180 on both sides of the support plate 170, one or more openings 175 passing through the support plate 170 may be formed. Since the electronic components 140 are fixed on both sides of the support plate 170 using the adhesive layer 180, a process for positioning the electronic components 140 can be stably and efficiently performed. Meanwhile, the raw material of the adhesive layer 180 is not particularly limited, but an epoxy resin including SiO₂ as a filler may be used to form the adhesive layer 180.

The electronic components 140 are electrically connected to a printed circuit board and perform specific functions. Examples of the electronic components 140 may include active components such as semiconductor components and passive components such as capacitors. Here, the electronic components 140 may be disposed in a face-up manner in order to connect them to circuit layers 160 formed on the exposed surfaces of the insulation layer 150 through vias 165. Further, since the two electronic components 140 are disposed in the cavity 130 in two stages to form an upward and downward symmetrical structure, there is an advantage in that the stability of a printed circuit board can be ensured and the bi-directional electrical connection of a printed circuit board can be realized.

The insulation layer 150, which serves to bury the two electronic components 140 disposed in the cavity 130, is applied on both sides of the metal substrate 110 in a semi-hardened state, charged in the cavity, and then hardened. Here, the insulation layer 150 may be formed of an insulating material commonly used in printed circuit boards, for example, ABF (Ajinomoto Build-up Film), prepreg or the like.

The circuit layers 160 are formed on the exposed surfaces of the insulation layer 150, and are connected to the connection terminals 145 of the electronic components 140 through the vias 165. Here, the circuit layers 160 including the vias 165 may be formed by a semi-additive process (SAP), a modified semi-additive process (MSAP) or a subtractive process. Further, the two circuit layers 160 formed on the lower and upper exposed surfaces of the insulation layer 150 can be connected to each other by forming through-holes 190 which pass through the insulation layer 150 and the metal substrate 110 and which communicate with the circuit layers 160.

Meanwhile, solder resist layers 193 may be formed on the outermost of the electronic component-embedded printed circuit board 100 according to this embodiment. The solder resist layers 193, which are made of a heat-resistant coating material, serve to protect the circuit layers 160 such that solder is not applied on the circuit layers 160 at the time of soldering. Further, in order to electrically connect the printed circuit board 100 with external circuits, holes 195 may be formed in the solder resist layers 193 to expose pads.

The electronic component-embedded printed circuit board 100 according to this embodiment is advantageous in that the heat generated from the electronic components 140 can be effectively emitted because the metal substrate 110 is used instead of a conventional insulating material, and in that the warpage of the electronic component-embedded printed circuit board 100 can be prevented because the metal substrate 110 has relatively high rigidity. Further, the electronic component-embedded printed circuit board 100 is advantageous in that its overall structural stability can be ensured because the two electronic components 140 are disposed in two stages.

FIG. 3 is a sectional view showing an electronic component-embedded printed circuit board according to a second embodiment of the present invention.

The electronic component-embedded printed circuit board 200 according to the second embodiment of the present invention is different from the above-mentioned electronic component-embedded printed circuit board 100 according to the first embodiment of the present invention in the structure of the metal substrate 110. Therefore, in this embodiment, the metal substrate 110 will be chiefly described, and the description overlapping with the first embodiment will be omitted.

The electronic component-embedded printed circuit board 200 according to this embodiment includes two metal substrates 110, and these two metal substrates 110 are disposed in two stages. Here, each of the two metal substrates 110 is provided with a cavity 130 and an anodic oxide film 120. Further, two electronic components 140 are embedded in their respective substrates 110. In order to realize an upward and downward symmetrical structure of the electronic components 140, the two electronic components may be disposed at corresponding positions.

Meanwhile, an adhesive layer 180 is provided between the two metal substrates 110 disposed in two stages, and serves to fix the two metal substrates 110 to each other. Here, the adhesive layer 180 may be provided between the cavities 130 and between the electronic components 140 as well as between the two metal substrates 110.

FIGS. 4 to 9 are sectional views sequentially showing a method of manufacturing the electronic component-embedded printed circuit board according to the first embodiment of the present invention.

As shown in FIGS. 4 to 9, the method of manufacturing the electronic component-embedded printed circuit board according to the first embodiment of the present invention includes the steps of: (A) forming a cavity 130 in a metal substrate 110 and then forming an anodic oxide film 120 over the entire surface of the metal substrate 110; (B) disposing two electronic components 140 in the cavity 130 in two stages; (C) forming an insulation layer 150 on both sides of the metal substrate 110 to bury the electronic components 140 disposed in the cavity 130; and (D) forming circuit layers 160 including vias 165 connected with connecting terminals 145 of the electronic components 140 on the exposed surfaces of the insulation layer 150.

First, as shown in FIG. 4, a cavity 130 is formed in a metal substrate 110. Here, the metal substrate 110 may be made of a metal having high rigidity and excellent thermal conductivity, such as aluminum (Al), magnesium (Mg), titanium (Ti) or the like. Although methods of forming the cavity 130 are not particularly limited, the cavity 130 may be formed by removing the predetermined portion of the metal substrate 110 through a wet etching process or a dry etching process. In this case, a support plate 170 for dividing the cavity 130 into two parts in a thickness direction may be formed by leaving behind a predetermined thickness of the central portion of the metal substrate 110. The support plate 170 finally serves to support the electronic components 140. Further, in a subsequent process, an adhesive layer 180 is applied onto both sides of the support plate 170. In this case, in order to uniformly apply the adhesive layer 180 onto both sides of the support plate 170, one or more openings 175 passing through the support plate 170 may be formed.

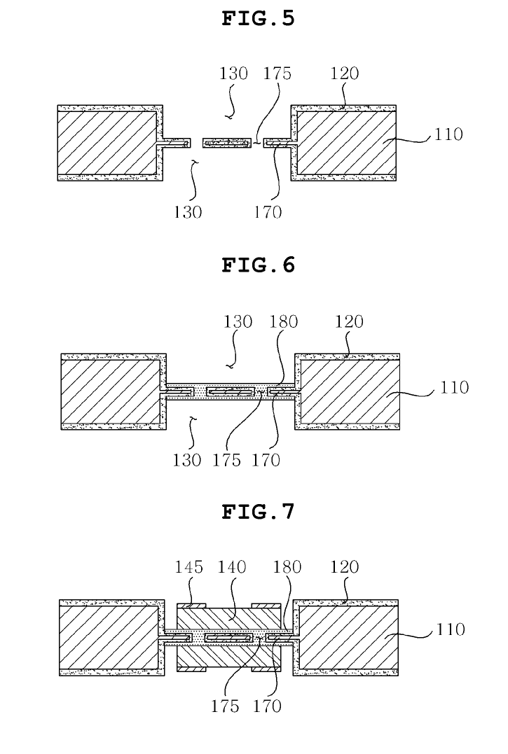

Subsequently, as shown in FIG. 5, an anodic oxide film 120 is formed over the entire surface of the metal substrate 110 through an anodic oxidation process. Here, the anodic oxide film 120 serves to prevent the short of the metal substrate 110, circuit patterns or the like, and is formed through the anodic oxidation process. For example, when the metal substrate 110 is made of aluminum (Al), the anodic oxide film 120 is made of alumina (Al₂O₃).

Subsequently, as shown in FIG. 6, an adhesive layer 180 is applied on both sides of the support plate 170. Here, the adhesive layer 180 serves to fix the electronic components 140 which are to be disposed in the cavity 130 in a subsequent process, and may be formed of an epoxy resin including SiO₂ as a filler.

Subsequently, as shown in FIG. 7, the two electronic components 140 are disposed in the cavity 130 in two stages. The two electronic components are fixed on both sides of the support plate 170 by the adhesive layer 180 applied on the support plate 170 after being disposed on both sides of the support plate 170 formed through the above-mentioned process. Since the electronic components 140 are fixed on both sides of the support plate 170 using the adhesive layer 180 applied on the support plate, a process for positioning the electronic components 140 can be stably and efficiently performed. Meanwhile, the electronic components 140 may be active components or passive components, and may be disposed in a face-up manner in order to connect the connection terminals 145 of the electronic components 140 to circuit layers 160 through vias 165.

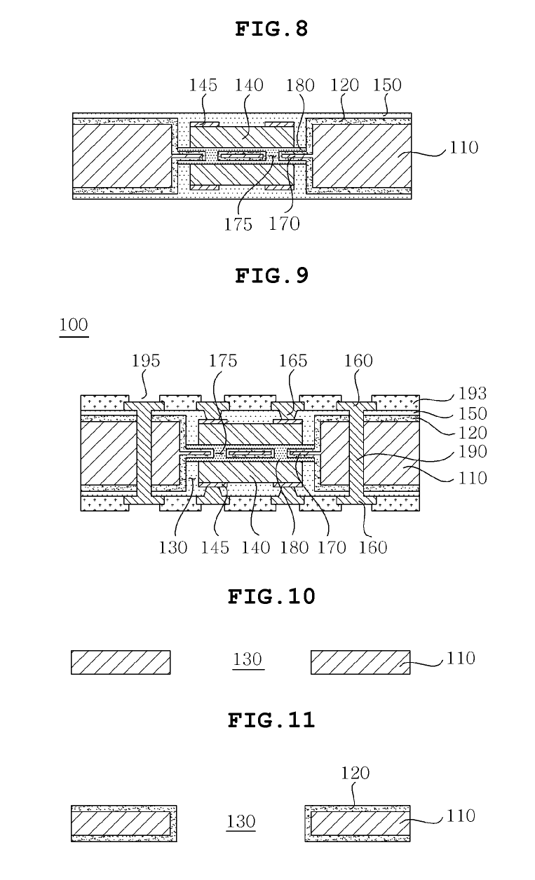

Subsequently, as shown in FIG. 8, an insulation layer 150 is applied on both sides of the metal substrate 110 to bury the electronic components 140. Here, the insulation layer 150 is applied on both sides of the metal substrate 110 in a semi-hardened state, charged in the cavity, and then hardened. The insulation layer 150 may be formed of a commonly-used insulating material, for example, ABF (Ajinomoto Build-up Film), prepreg or the like.

Subsequently, as shown in FIG. 9, circuit layers 160 including vias 165 are formed on the exposed surfaces of the insulation layer 150. Here, the circuit layers 160 including the vias 165 may be formed by a semi-additive process (SAP), a modified semi-additive process (MSAP) or a subtractive process. In this case, the circuit layers 160 are connected to the connection terminals 145 of the electronic components 140 through the vias 165. Further, in order to connect the two circuit layers 160 formed on the lower and upper exposed surfaces of the insulation layer 150 to each other, through-holes 190 passing through the insulation layer 150 and the metal substrate 110 may be formed.

Meanwhile, solder resist layers 193 may be formed on the outermost of the electronic component-embedded printed circuit board 100 in order to prevent solder from being applied on the circuit layers 160. Further, in order to electrically connect the printed circuit board 100 with external circuits, holes 195 may be formed in the solder resist layers 193 to expose pads.

FIGS. 10 to 15 are sectional views sequentially showing a method of manufacturing the electronic component-embedded printed circuit board according to the second embodiment of the present invention.

As shown in FIGS. 10 to 15, the method of manufacturing the electronic component-embedded printed circuit board according to the second embodiment of the present invention includes the steps of: (A) forming cavities 130 in two metal substrates 110 and then forming anodic oxide films 120 over the entire surfaces of the two metal substrates 110 through an anodic oxidation process; (B) disposing electronic components 140 in the cavities 130; (C) applying insulation layers 150 onto the one sides of the respective two metal substrates 110 to bury the electronic components 140 disposed in the cavities 130; (D) attaching the two metal substrates 110 provided with the insulation layers 150 to each other using an adhesive layer 180; and (E) forming circuit layers 160 including vias 165 connected with connecting terminals 145 of the electronic components 140 on the exposed surfaces of the insulation layers 150.

The method of manufacturing the electronic component-embedded printed circuit board 200 according to the second embodiment of the present invention is different from the above-mentioned method of manufacturing the electronic component-embedded printed circuit board 100 according to the first embodiment of the present invention in the structure of the metal substrate 110. Therefore, in this embodiment, the metal substrate 110 will be chiefly described, and other constituents will be briefly described. Meanwhile, only one metal substrate 110 is shown in FIGS. 10 to 13 because two metal substrates 110 undergo the same processes.

First, as shown in FIGS. 10 and 11, a cavity 130 is formed in a metal substrate 110, and then an anodic oxide film 120 is formed over the entire surface of the metal substrate 110. Here, the cavity 130 is formed by removing the predetermined portion of the metal substrate 110 through a wet etching process or a dry etching process, and the anodic oxide film 120 is formed over the entire surface of the metal substrate 110 through an anodic oxidation process. Meanwhile, as described, when the metal substrate 110 is made of aluminum (Al), the anodic oxide film 120 is made of alumina (Al₂O₃).

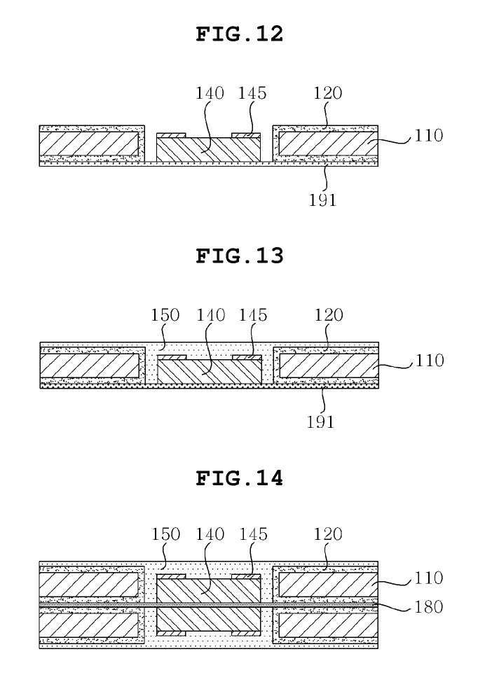

Subsequently, as shown in FIG. 12, an electronic component 140 is disposed in the cavity 130. Here, a tape 191 for supporting the electronic component 140 is attached to the lower surface of the metal substrate 110, and the electronic component 140 is mounted on the tape 191 in a face-up manner.

Subsequently, as shown in FIG. 13, an insulation layer 150 is applied onto the upper surface of the metal substrate 110 to bury the electronic component 140. The insulation layer 150 is charged in the cavity 130 to fix the electronic component 140, and then the tape 191 attached to the lower surface of the metal substrate 110 is removed.

Subsequently, as shown in FIG. 14, the two metal substrates 110 provided with the insulation layers 150 are attached to each other using an adhesive layer 180. Here, the adhesive layer 180 serves to fix the two metal substrates 110 as well as the electronic components 140, compared to the first embodiment where the adhesive layer serves to fix only the electronic components 140. However, as in the first embodiment, the adhesive layer may be formed of an epoxy resin including SiO₂ as a filler.

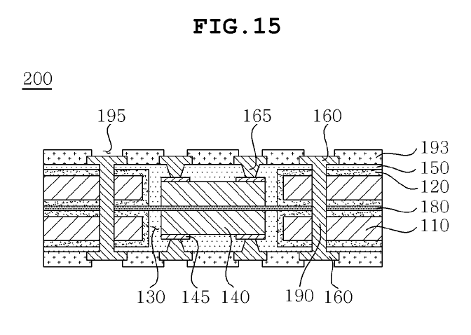

Subsequently, as shown in FIG. 15, circuit layers 160 including vias 165 are formed on the exposed surfaces of the insulation layers 150. Here, the circuit layers 160 are connected to the connection terminals 145 of the electronic components 140 through the vias 165. In order to connect the two circuit layers 160 formed on the exposed surfaces of the upper and lower insulation layers 150 to each other, through-holes 190 passing through the insulation layers 150 and the metal substrates 110 may be formed. Further, solder resist layers 193 may be formed on the outermost of the electronic component-embedded printed circuit board 100 in order to prevent solder from being applied on the circuit layers 160.

As described above, according to the present invention, since a metal substrate is used instead of a conventional insulating material, its performance of radiating the heat generated from an electronic component can be improved, and its production cost can be reduced.

Further, according to the present invention, since two electronic components are disposed in two stages, the directions in which the two electronic components are respectively warped can conflict with each other, thus ensuring the overall structural stability of the printed circuit board.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. An electronic component-embedded printed circuit board, comprising:
a metal substrate including an anodic oxide film formed over the entire surface thereof;
two electronic components disposed in a cavity formed in the metal substrate in two stages;
an insulation layer formed on both sides of the metal substrate to bury the electronic components disposed in the cavity; and
circuit layers including vias connected with connecting terminals of the electronic components and formed on exposed surfaces of the insulation layer.

2. The electronic component-embedded printed circuit board according to claim 1, further comprising: a support plate which is formed in the cavity to divide the cavity into two parts in a thickness direction and which supports the two electronic components on both sides thereof.

3. The electronic component-embedded printed circuit board according to claim 2, further comprising: an adhesive layer applied onto both sides of the support plate to fix the two electronic components.

4. The electronic component-embedded printed circuit board according to claim 2, further comprising: one or more openings passing through the support plate.

5. The electronic component-embedded printed circuit board according to claim 2, wherein the support plate is extended from the metal substrate and is integrated therewith.

6. The electronic component-embedded printed circuit board according to claim 1, further comprising: two metal substrates disposed in two stages; and an adhesive layer attaching the two metal substrates to each other.

7. The electronic component-embedded printed circuit board according to claim 1, further comprising: through-holes which pass through the insulation layer and the metal substrate and which communicate with the circuit layers.

7. The electronic component-embedded printed circuit board according to claim 1, to wherein the metal substrate is made of aluminum (Al), and the anodic oxide film is made of alumina (Al₂O₃).

9. A method of manufacturing an electronic component-embedded printed circuit board, comprising:
forming a cavity in a metal substrate and then forming an anodic oxide film over the entire surface of the metal substrate;
disposing two electronic components in the cavity in two stages;
forming an insulation layer on both sides of the metal substrate to bury the electronic components disposed in the cavity; and
forming circuit layers including vias connected with connecting terminals of the electronic components on the exposed surfaces of the insulation layer.

10. The method of manufacturing an electronic component-embedded printed circuit board according to claim 9, wherein, in the forming of the cavity, a support plate for dividing the cavity into two parts in a thickness direction is formed by leaving the central portion of the metal substrate to a predetermined thickness when the cavity is formed by removing the predetermined portion of the metal substrate through an etching process.

11. The method of manufacturing an electronic component-embedded printed circuit board according to claim 10, wherein, in the disposing of the two electronic components, an adhesive layer is applied onto both sides of the support plate to fix the two electronic components.

12. The method of manufacturing an electronic component-embedded printed circuit board according to claim 10, wherein, in the forming of the cavity, one or more openings passing through the support plate are formed when the support plate is formed.

13. The method of manufacturing an electronic component-embedded printed circuit board according to claim 9, wherein the forming of the circuit layers further comprises: forming through-holes which pass through the insulation layer and the metal substrate and which communicate with the circuit layers.

14. The method of manufacturing an electronic component-embedded printed circuit board according to claim 9, wherein, in the forming of the cavity and the anodic oxide film, the metal substrate is made of aluminum (Al), and the anodic oxide film is made of alumina (Al₂O₃).

15. A method of manufacturing an electronic component-embedded printed circuit board, comprising:
forming cavities in two metal substrates and then forming anodic oxide films over the entire surfaces of the two metal substrates through an anodic oxidation process;
disposing electronic components in the cavities;
applying insulation layers onto the one sides of the respective two metal substrates to bury the electronic components disposed in the cavities;
attaching the two metal substrates provided with the insulation layers to each other using an adhesive layer; and
forming circuit layers including vias connected with connecting terminals of the electronic components on the exposed surfaces of the insulation layers.

16. The method of manufacturing an electronic component-embedded printed circuit board according to claim 15, wherein the forming of the circuit layers further comprises: forming through-holes which pass through the insulation layers and the metal substrates and which communicate with the circuit layers.

17. The method of manufacturing an electronic component-embedded printed circuit board according to claim 15, wherein, in the forming of the cavity and the anodic oxide film, each of the metal substrates is made of aluminum (Al), and each of the anodic oxide films is made of alumina (Al₂O₃).
